(19) United States
(12) Patent Application Publication
(10) Pub. No.: US 2010/0330734 A1
(43) Pub. Date: Dec. 30, 2010

(54) SOLAR CELL AND MANUFACTURING METHOD THEREOF

(75) Inventors: Mitsuhiro Matsumoto, Gifu-shi (JP); Makoto Nakagawa, Kobe-shi (JP)

Correspondence Address: DITTHAVONG MORI & STEINER, P.C., 918 Prince Street, Alexandria, VA, 22314, US

(73) Assignee: SANYO ELECTRIC CO., LTD., Moriguchi-shi (JP)

(21) Appl. No.: 12/825,518

(22) Filed: Jun. 29, 2010

(30) Foreign Application Priority Data
Jun. 30, 2009 (JP) 2009-155498
Jun. 30, 2009 (JP) 2009-155499

(51) Int. Cl. H01L 31/0312

(52) U.S. Cl. 438/93; 257/E31.023; 438/96

(57) ABSTRACT

In a manufacturing process of a solar cell comprising an amorphous silicon unit in which a p-type layer, an i-type layer, and an n-type layer are layered, in a step of forming the p-type layer, a doping concentration of a p-type dopant included in the p-type layer is increased as a distance from the i-type layer is increased, and in particular, a high-absorption amorphous silicon carbide layer and a low-absorption amorphous silicon carbide layer are consecutively formed while a state of plasma generation is maintained.

### CROSS-REFERENCE TO RELATED APPLICATIONS

The entire disclosure of Japanese Patent Application Nos. 2009-155498 and 2009-155499 filed on Jun. 30, 2009, including specification, claims, drawings, and abstract, is incorporated herein by reference in its entirety.

### BACKGROUND

1. Technical Field

The present invention relates to a solar cell and a manufacturing method of a solar cell.

2. Related Art

Solar cells are known in which polycrystalline silicon, microcrystalline silicon, or amorphous silicon is used. In particular, a solar cell in which microcrystalline or amorphous silicon thin films are layered has attracted much attention in view of resource consumption, reduction of cost, and improvement in efficiency.

In general, a thin film solar cell is formed by sequentially layering a first electrode, one or more semiconductor thin film photoelectric conversion cells, and a second electrode over a substrate having an insulating surface. Each solar cell unit is formed by layering a p-type layer, an i-type layer, and an n-type layer from a side of incidence of light.

As a method of improving the conversion efficiency of the thin film solar cell, a method is known in which two or more types of photoelectric conversion cells are layered in the direction of light incidence. A first solar cell unit having a photoelectric conversion layer with a wider band gap is placed on the light incidence side of the thin film solar cell, and then, a second solar cell unit having a photoelectric conversion layer having a narrower band gap than the first solar cell unit is placed. With this configuration, photoelectric conversion is enabled for a wide wavelength range of the incident light, and the conversion efficiency of the overall device can be improved.

For example, a structure is known in which an amorphous silicon (a-Si) solar cell unit is set as a top cell and a microcrystalline silicon (μc-Si) solar cell unit is set as a bottom cell.

In order to improve the conversion efficiency of the thin film solar cell, it is necessary to optimize the characteristics of the thin films of the solar cell, and improve an open voltage Voc, a short-circuit current density Jsc, and a fill factor FF.

### SUMMARY

According to one aspect of the present invention, there is provided a method of manufacturing a solar cell, comprising a first step in which a p-type layer is formed, a second step in which an i-type amorphous silicon layer is layered and formed over the p-type layer, and a third step in which an n-type layer doped with an n-type dopant is layered and formed over the i-type amorphous silicon layer, wherein, in the first step, a doping concentration of a p-type dopant included in the p-type layer is increased as a distance from the i-type amorphous silicon layer is increased.

According to another aspect of the present invention, there is provided a method of manufacturing a solar cell, comprising a first step in which a p-type layer is formed, a second step in which an i-type amorphous silicon layer is layered and formed over the p-type layer, and a third step in which an n-type layer doped with an n-type dopant is layered and formed over the i-type amorphous silicon layer, wherein, in the first step, a high-absorption amorphous silicon carbide layer doped with a p-type dopant in a first dopant concentration, a low-absorption amorphous silicon carbide layer formed on a side nearer to the i-type amorphous silicon layer than is the high-absorption amorphous silicon carbide layer and doped with the p-type dopant in a second dopant concentration which is lower than the first dopant concentration, and a silicon carbide buffer layer formed between the low-absorption amorphous silicon carbide layer and the i-type amorphous silicon layer, are formed.

### BRIEF DESCRIPTION OF THE DRAWINGS

A preferred embodiment of the present invention will be described in further detail based on the following drawings, wherein:

FIG. 1 is a diagram showing a structure of a tandem-type solar cell in a preferred embodiment of the present invention; and

FIG. 2 is a diagram showing a structure of an a-Si unit of the tandem-type solar cell in the preferred embodiment of the present invention.

### DETAILED DESCRIPTION

### Basic Structure

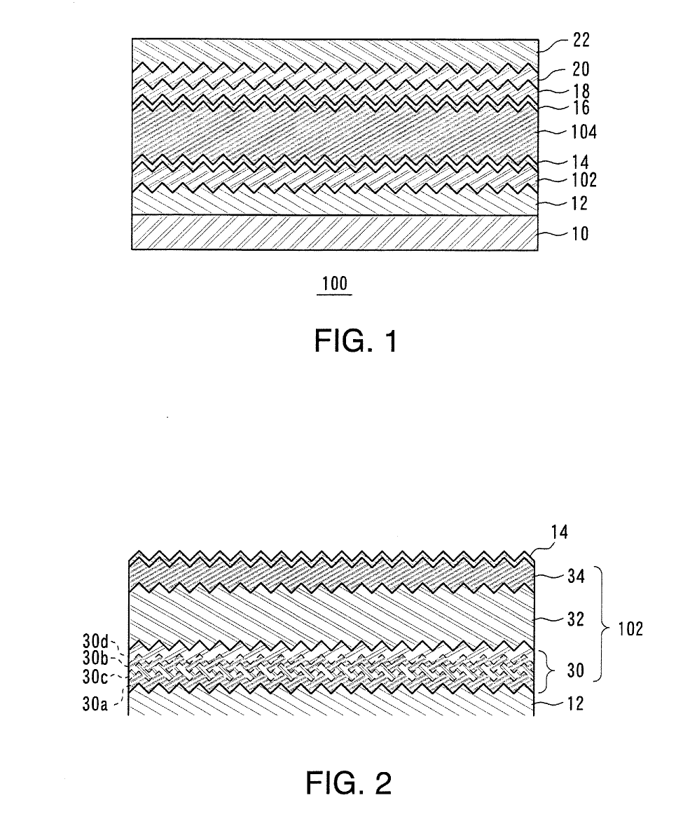

FIG. 1 is a cross sectional diagram showing a structure of a tandem-type solar cell 100 in a preferred embodiment of the present invention. The tandem-type solar cell 100 in the present embodiment has a structure in which a transparent insulating substrate 10 is set at a light incidence side, and a transparent conductive film 12, an amorphous silicon (a-Si) (photoelectric conversion) unit 102 functioning as a top cell and having a wide band gap, an intermediate layer 14, a microcrystalline silicon (μc-Si) (photoelectric conversion) unit 104 functioning as a bottom cell and having a narrower band gap than the a-Si unit 102, a first backside electrode layer 16, a second backside electrode layer 18, a bonding layer 200, and a protective film 22, are layered from the light incidence side.

A structure and a method of manufacturing the tandem-type solar cell 100 in the preferred embodiment of the present invention will now be described. As the tandem-type solar cell 100 in the present embodiment has a characteristic of a p-type layer included in the a-Si unit 102, the p-type layer in the a-Si unit 102 will be particularly described in detail.

As the transparent insulating substrate 10, a material having light transmittance at least in a visible light wavelength region such as, for example, a glass substrate, a plastic substrate, or the like, may be used. The transparent conductive film 12 is formed over the transparent insulating substrate 10. For the transparent conductive film 12, it is preferable to use at least one of or a combination of a plurality of transparent conductive oxides (TCO) in which tin (Sn), antimony (Sb), fluorine (F), aluminum (Al), or the like is doped into tin oxide (SnO₂), zinc oxide (ZnO), indium tin oxide (ITO), or the like. In particular, zinc oxide (ZnO) is preferable because it has a high light transmittance, a low resistivity, and a high plasma endurance characteristic. The transparent conductive film 12 can be formed, for example, through sputtering. A thickness of the transparent conductive film 12 is preferably set in a range of greater than or equal to 0.5 μm and less than or equal to 5 μm. In addition, it is preferable to provide unevenness having a light confinement effect on a surface of the transparent conductive film 12.

Silicon-based thin films, that is, a p-type layer 30, an i-type layer 32, and an n-type layer 34, are sequentially layered over the transparent conductive film 12, to form the a-Si unit 102. FIG. 2 shows an enlarged cross sectional view of the portion of the a-Si unit 102.

The a-Si unit 102 may be formed through plasma CVD in which mixture gas of silicon-containing gas such as silane (SiH₄), disilane (Si₂H₆), and dichlorosilane (SiH₂Cl₂), carbon-containing gas such as methane (CH₄), p-type dopant-containing gas such as diborane (B₂H₆), n-type dopant-containing gas such as phosphine (PH₃), and dilution gas such as hydrogen (H₂) is made into plasma and a film is formed.

For the plasma CVD, for example, RF plasma CVD of 13.56 MHz is preferably applied. The RF plasma CVD may be of a parallel plate-type. Alternatively, a configuration may be employed in which a gas shower hole for supplying the mixture gas of the material is provided on a side of the parallel plate-type electrodes on which the transparent insulating substrate 10 is not placed. An input power density of the plasma is preferably greater than or equal to 5 mW/cm² and less than or equal to 100 mW/cm².

In general, the p-type layer 30, the i-type layer 32, and the n-type layer 34 are formed in different film formation chambers. The film formation chamber can be vacuumed using a vacuum pump, and an electrode for the RF plasma CVD is built into the film formation chamber. In addition, a transporting device of the transparent insulating substrate 10, a power supply and a matching device for the RF plasma CVD, pipes for supplying gas, etc. are provided.

The structure and manufacturing method of the p-type layer 30 will be described later. For the i-type layer 32, a non-doped amorphous silicon film formed over the p-type layer 30 and having a thickness of greater than or equal to 50 nm and less than or equal to 500 nm is employed. A film characteristic of the i-type layer can be changed by adjusting the mixture ratios of silicon-containing gas and dilution gas, pressure, and plasma generating high-frequency power. In addition, the i-type layer 32 forms a power generation layer of the a-Si unit 102. For the n-type layer 34, an n-type amorphous silicon layer (n-type α-Si:H) or an n-type microcrystalline silicon layer (n-type μc-Si:H) formed over the i-type layer 32, doped with an n-type dopant (such as phosphorus), and having a thickness of greater than or equal to 10 nm and less than or equal to 100 nm is employed. The film characteristic of the n-type layer 34 can be changed by adjusting the mixture ratios of the silicon-containing gas, carbon-containing gas, n-type dopant-containing gas, and dilution gas, pressure, and plasma generating high-frequency power.

The intermediate layer 14 is formed over the a-Si unit 102. For the intermediate layer 14, it is preferable to use the transparent conductive oxide (TCO) such as zinc oxide (ZnO) and silicon oxide (SiOx). In particular, it is preferable to use zinc oxide (ZnO) or silicon oxide (SiOx) doped with magnesium Mg. The intermediate layer 14 may be formed, for example, through sputtering. A thickness of the intermediate layer 14 is preferably in a range of greater than or equal to 10 nm and less than or equal to 200 nm. Alternatively, it is also possible to not provide the intermediate layer 14.

The μc-Si unit 104 in which a p-type layer, an i-type layer, and an n-type layer are sequentially layered is formed over the intermediate layer 14. The μc-Si unit 104 may be formed through plasma CVD in which mixture gas of silicon-containing gas such as silane (SiH₄), disilane (Si₂H₆), dichlorosilane (SiH₂Cl₂), carbon-containing gas such as methane (CH₄), p-type dopant-containing gas such as diborane (B₂H₆), n-type dopant-containing gas such as phosphine (PH₃), and dilution gas such as hydrogen (H₂) is made into plasma and a film is formed.

Similar to the a-Si unit 102, for the plasma CVD, for example, RF plasma CVD of 13.56 MHz is preferably applied. The RF plasma CVD may be of the parallel plate-type. Alternatively, a configuration may be employed in which a gas shower hole for supplying the mixture gas of the material is provided on a side of the parallel plate-type electrode on which the transparent insulating substrate 10 is not placed. The input power density of the plasma is preferably set to greater than or equal to 5 mW/cm² and less than or equal to 100 mW/cm².

For example, the μc-Si unit 104 is formed by layering a p-type microcrystalline silicon layer (p-type μc-Si:H) having a thickness of greater than or equal to 5 nm and less than or equal to 50 nm and doped with boron, a non-doped i-type microcrystalline silicon layer (i-type μc-Si:H) having a thickness of greater than or equal to 0.5 μm and less than or equal to 5 μm, and an n-type microcrystalline silicon layer (n-type μc-Si:H) having a thickness of greater than or equal to 5 nm and less than or equal to 50 nm and doped with phosphorus.

The unit is not limited to the μc-Si unit 104, and any unit may be used so long as the i-type microcrystalline silicon layer (i-type μc-Si:H) is used as a power generation layer.

A layered structure of a transparent conductive oxide (TCO) and a reflective metal is formed over the μc-Si unit 104 as the first backside electrode layer 16 and the second backside electrode layer 18. As the first backside electrode layer 16, a transparent conductive oxide (TCO) such as tin oxide (SnO₂), zinc oxide (ZnO), and indium tin oxide (ITO) is used. As the second backside electrode layer 18, a metal such as silver (Ag) and aluminum (Al) can be used. The TCO may be formed, for example, through sputtering. The first backside electrode layer 16 and the second backside electrode layer 18 are preferably formed to a total thickness of approximately 1 μm. In addition, it is preferable to form unevenness on the surface of at least one of the first backside electrode layer 16 and the second backside electrode layer 18, to improve the light confinement effect.

The surface of the second backside electrode layer 18 is covered with the protective film 22 by the bonding layer 200. The bonding layer 200 and the protective film 22 may be formed of a resin material such as EVA and polyimide. With such a configuration, it is possible to prevent intrusion of moisture or the like into the power generation layer of the tandem-type solar cell 100.

Alternatively, a YAG laser (with a basic wave of 1064 nm and second harmonics of 532 nm) may be used to separate and pattern the transparent conductive film 12, the a-Si unit 102, the intermediate layer 14, the μc-Si unit 104, the first backside electrode layer 16, and the second backside electrode layer 18, to achieve a structure in which a plurality of cells are connected in series.

The basic structure of the tandem-type solar cell 100 in the preferred embodiment of the present invention has been described. The structure and manufacturing method of the p-type layer 30 in the preferred embodiment will now be described.

### <P-Type Layer>

The p-type layer 30 is formed over the transparent conductive film 12. The p-type layer 30 includes an amorphous silicon carbide layer in which an absorption coefficient with respect to light of a particular wavelength changes with an increase in the thickness from the transparent conductive film 12 toward the i-type layer 32. A reference wavelength for the particular wavelength may be 600 nm.

More specifically, for example, because the absorption coefficient of the amorphous silicon carbide layer changes according to the doping concentration of the p-type dopant, the doping concentration of the p-type dopant may be set to become higher as the distance from the i-type layer 32 is increased. In this case, the doping concentration of the p-type dopant may be stepwise increased or continuously increased as the distance from the i-type layer 32 is increased.

In the case where the doping concentration is to be stepwise increased, first, a high-absorption amorphous silicon carbide layer 30a doped with the p-type dopant (such as boron) in a first doping concentration is formed over the transparent conductive film 12. Then, a low-absorption amorphous silicon carbide layer 30b doped with the p-type dopant (such as boron) in a second doping concentration lower than the first doping concentration may be formed over the high-absorption amorphous silicon carbide layer 30a. The second doping concentration is set to be ⅕ to 1/10 of the first doping concentration.

In this case, in the plasma CVD, while the plasma is being generated, the mixture ratios of the silicon-containing gas, carbon-containing gas, p-type dopant-containing gas, and dilution gas, pressure, and plasma generating high-frequency power may be adjusted, to consecutively form the high-absorption amorphous silicon carbide layer 30a and the low-absorption amorphous silicon carbide layer 30b. In this configuration, because the film formation conditions are continuously changed while the plasma is being generated, an interface layer 30c is formed between the high-absorption amorphous silicon carbide layer 30a and the low-absorption amorphous silicon carbide layer 30b. However, the interface layer 30c is formed as a very thin layer.

In this manner, by consecutively forming the high-absorption amorphous silicon carbide layer 30a and the low-absorption amorphous silicon carbide layer 30b while the plasma is being generated, it is possible to prevent formation of a plasma generated initial layer at the interface between the high-absorption amorphous silicon carbide layer 30a and the low-absorption amorphous silicon carbide layer 30b, so that the defect at the interface between the high-absorption amorphous silicon carbide layer 30a and the low-absorption amorphous silicon carbide layer 30b can be reduced and the open voltage Voc and the fill factor FF of the solar cell can be improved. However, when the thickness of the interface layer 30c is increased, the contact characteristic with the transparent conductive film 12 is reduced, and thus the thickness of the interface layer 30c must be adjusted.

When the doping concentration of the amorphous silicon carbide layer is to be continuously changed, the doping concentration of the amorphous silicon carbide layer at the side near the i-type layer 32 is set in a range of ⅕ to 1/10 of the doping concentration of the amorphous silicon carbide layer at the side near the transparent conductive film 12. In this case, in the plasma CVD, while the plasma is being generated, the mixture ratios of the silicon-containing gas, carbon-containing gas, p-type dopant-containing gas, and dilution gas, pressure, and plasma generating high-frequency power may be adjusted.

In addition, in order to adjust the band gap and avoid influences of plasma during formation of the i-type layer 32, a buffer layer 30d made of amorphous silicon carbide or microcrystalline silicon carbide is formed over the low-absorption amorphous silicon carbide layer 30b.

When the buffer layer 30d is formed, it is preferable to temporarily stop plasma after the low-absorption amorphous silicon carbide layer 30b is formed, stop the supply of the p-type dopant-containing gas, adjust the mixture ratios of the mixture gas, pressure, and plasma generating high-frequency power, and then generate plasma again, to stepwise form the buffer layer 30d. In this case, by stopping only the plasma and not supply of gas to transition from the film formation of the low-absorption amorphous silicon carbide layer 30b to the film formation of the buffer layer 30d, it is possible to prevent detachment of hydrogen from the surface of the low-absorption amorphous silicon carbide layer 30b, making it difficult for impurities (contaminations) attached on the chamber walls of the film formation chamber to hit the gas molecules and reach the surface of the low-absorption amorphous silicon carbide layer 30b, and to reduce a defect density at the interface between the low-absorption amorphous silicon carbide layer 30b and the buffer layer 30d. With this configuration, the open voltage Voc of the solar cell can be improved. In addition, the change of the doping concentration between the doped low-absorption amorphous silicon carbide layer 30b and the non-doped buffer layer 30d can be set to be abrupt.

In the case of the present embodiment, it is preferable to set the thickness of the high-absorption amorphous silicon carbide layer 30a or the thickness of the buffer layer 30d to be greatest in the p-type layer 30. Moreover, it is preferable that the thickness of the low-absorption amorphous silicon carbide layer 30b be lowest in the p-type layer 30. The thicknesses of the high-absorption amorphous silicon carbide layer 30a, the low-absorption amorphous silicon-carbide layer 30b, and the buffer layer 30d can be adjusted by adjusting the film formation times of the layers.

### EXAMPLES

Examples and comparative examples of the tandem-type solar cell 100 to which the p-type layer 30 of the above-described preferred embodiment is applied will now be described.

### Example 1

As the transparent insulating substrate 10, a glass substrate having a size of 33 cm×43 cm and a thickness of 4 mm was used. Over the transparent insulating substrate 10, a layer of SnO₂ having a thickness of 600 nm and having uneven shapes on the surface was formed through thermal CVD as the transparent conductive film 12. Then, the transparent conductive film 12 was patterned by a YAG laser in a strip shape. As the YAG laser, a YAG laser having a wavelength of 1064 nm, an energy density of 13 J/cm³, and a pulse frequency of 3 kHz was used.

Then, the high-absorption amorphous silicon carbide layer 30a, the low-absorption amorphous silicon carbide layer 30b, and the buffer layer 30d in the above-described preferred embodiment were formed with the film formation conditions as shown in steps 1 and 3 of TABLE 1. During the transition from the film formation of the high-absorption amorphous silicon carbide layer 30a to the film formation of the low-absorption amorphous silicon carbide layer 30b, as shown in step 2 of TABLE 1, the mixture ratios of the material gas were continuously adjusted without stopping the plasma and the film was formed. With this process, the interface layer 30c was formed between the high-absorption amorphous silicon carbide layer 30a and the low-absorption amorphous silicon carbide layer 30b. Based on the relationship between the film formation rate and the film formation time determined from the film formation conditions, as shown in TABLE 4, the thickness of the high-absorption amorphous silicon carbide layer 30a was determined to be approximately 6.75 nm, the thickness of the interface layer 30c was determined to be approximately 0.5 nm, and the thickness of the low-absorption amorphous silicon carbide layer 30b was determined to be approximately 2.75 nm.

In addition, during the transition from the film formation of the low-absorption amorphous silicon carbide layer 30b to the film formation of the buffer layer 30d, the film formation chamber was once vacuumed and discharged in the state where the plasma was stopped and the flow of the gas was not continued. Then, the buffer layer 30d was formed with the film formation conditions shown in step 5 of TABLE 1. The buffer layer 30d was formed to a thickness of approximately 10 nm. The i-type layer 32 and the n-type layer 34 of the a-Si unit 102 were formed with the film formation conditions as shown in TABLE 2, and the p-type layer, the i-type layer, and the n-type layer of the μc-Si unit 104 were formed with the conditions shown in TABLE 3.

TABLE 1

| | | SUBSTRATE | | REACTION | |
|---|---|---|---|---|---|
| | | TEMPERATURE | GAS FLOW RATE | PRESSURE | RF POWER |
| STEP | LAYER | (° c.) | (sccm) | (Pa) | (W) |
| 1 | HIGH-ABSORPTION | 180 | SiH₄: 40 | 80 | 30 |
| | AMORPHOUS SILICON | | CH₄: 80 | | |
| | CARBIDE LAYER 30a | | B₂H₆: 0.12 | | |
| | | | H₂: 400 | | |
| 2 | INTERFACE LAYER | 180 | SiH₄: 40 | 80 | 30 |
| | 30c | | CH₄: 80 | | |
| | | | B₂H₆: 0.12 → 0.01 | | |
| | | | H2: 400 | | |
| 3 | LOW-ABSORPTION | 180 | SiH₄: 40 | 80 | 30 |
| | AMORPHOUS SILICON | | CH₄: 80 | | |
| | CARBIDE LAYER 30b | | B₂H₆: 0.01 | | |
| | | | H₂: 400 | | |
| 4 | GAS FLOW BEFORE | 180 | SiH₄: 40 → 20 | 80 | 0 |
| | FORMATION OF | | CH₄: 80 → 10 | | |
| | BUFFER LAYER 30d | | B₂H₆: 0.01 → 0 | | |
| | | | H₂: 400 → 2000 | | |
| 5 | BUFFER LAYER 30d | 180 | SiH₄: 20 | 80 | 30 |
| | | | CH₄: 10 | | |
| | | | H₂: 2000 | | |

TABLE 2

| | SUBSTRATE | GAS FLOW | REACTION | | |
|---|---|---|---|---|---|
| | TEMPERATURE | RATE | PRESSURE | RF POWER | |
| LAYER | (° c.) | (sccm) | (Pa) | (W) | THICKNESS |
| i-TYPE | 200 | SiH₄: 300 | 106 | 20 | 250 |
| LAYER | | H₂: 2000 | | | |
| n-TYPE | 180 | SiH₄: 300 | 133 | 20 | 25 |
| LAYER | | H₂: 2000 | | | |
| | | PH₃: 5 | | | |

TABLE 3

| | SUBSTRATE | GAS FLOW | REACTION | | |
|---|---|---|---|---|---|
| | TEMPERATURE | RATE | PRESSURE | RF POWER | |
| LAYER | (° c.) | (sccm) | (Pa) | (W) | THICKNESS |
| p-TYPE | 180 | SiH₄: 10 | 106 | 10 | 10 |
| LAYER | | H₂: 2000 | | | |
| | | B₂H₆: 0.03 | | | |
| i-TYPE | 200 | SiH₄: 100 | 133 | 20 | 2000 |
| LAYER | | H₂: 2000 | | | |
| n-TYPE | 200 | SiH₄: 10 | 133 | 20 | 20 |
| LAYER | | H₂: 2000 | | | |
| | | PH₃: 0.05 | | | |

TABLE 4

| | | | LOW-ABSORPTION | GAS FLOW | |
|---|---|---|---|---|---|
| | HIGH-ABSORPTION | | AMORPHOUS | BEFORE | |
| | AMORPHOUS | | SILICON | FORMATION | BUFFER |
| | SILICON CARBIDE | INTERFACE | CARBIDE LAYER | OF BUFFER | LAYER |
| | LAYER 30A | LAYER 30c | 30b | LAYER 30d | 30d |
| EXAMPLE 1 | 6.75 nm | 0.5 nm | 2.75 nm | STOPPED | 10 nm |
| EXAMPLE 2 | 6.5 nm | 1 nm | 2.5 nm | STOPPED | 10 nm |
| EXAMPLE 3 | 7 nm | NONE | 3 nm | CONTINUED | 10 nm |
| COMPARATIVE | 7 nm | NONE | 3 nm | STOPPED | 10 nm |
| EXAMPLE 1 | | | | | |
| COMPARATIVE | NONE | 10 nm | NONE | STOPPED | 10 nm |
| EXAMPLE 2 | | | | | |

Then, the YAG laser was radiated on a position aside from the patterning position of the transparent conductive film 12 by 50 μm, to pattern the a-Si unit 102 and the μc-Si unit 104 in a strip shape. As the YAG laser, a YAG laser having an energy density of 0.7 J/cm³ and a pulse frequency of 3 kHz was used.

A ZnO film was then formed as the first backside electrode layer 16 through sputtering and an Ag electrode was formed as the second backside electrode layer 18 through sputtering. YAG laser was radiated at a position aside from the patterning position of the a-Si unit 102 and the μc-Si unit 104 by 50 μm, to pattern the first backside electrode layer 16 and the second backside electrode layer 18 in a strip shape. As the YAG laser, a YAG laser having an energy density of 0.7 J/cm³ and a pulse frequency of 4 kHz was used.

### Example 2

The transition time during the transition from the film formation of the high-absorption amorphous silicon carbide layer 30a to the film formation of the low-absorption amorphous silicon carbide layer 30b was set longer compared to Example 1, and the film formation time of the high-absorption amorphous silicon carbide layer 30a and the film formation time of the low-absorption amorphous silicon carbide layer 30b were shortened so that a total thickness of the high-absorption amorphous silicon carbide layer 30a, the low-absorption amorphous silicon carbide layer 30b, and the interface layer 30c was equal to that in Example 1. The other conditions were set basically identical to those in Example 1.

As shown in TABLE 4, based on the relationship between the film formation rate and the film formation time determined from the film formation conditions, the thickness of the high-absorption amorphous silicon carbide layer 30a was determined to be approximately 6.5 nm, the thickness of the interface layer 30c was determined to be approximately 1 nm, and the thickness of the low-absorption amorphous silicon carbide layer 30b was determined to be approximately 2.5 nm.

### Example 3

During transition from the film formation of the high-absorption amorphous silicon carbide layer 30a to the film formation of the low-absorption amorphous silicon carbide layer 30b, the plasma was once stopped, the high-absorption amorphous silicon carbide layer 30a and the low-absorption amorphous silicon carbide layer 30b were inconsecutively formed, and the interface layer 30c was not formed. In addition, the film formation time of the high-absorption amorphous silicon carbide layer 30a and the film formation time of the low-absorption amorphous silicon carbide layer 30b were adjusted such that a total thickness of the high-absorption amorphous silicon carbide layer 30a and the low-absorption amorphous silicon carbide layer 30b was equal to the total thickness of the high-absorption amorphous silicon carbide layer 30a, the low-absorption amorphous silicon carbide layer 30b, and the interface layer 30c in Example 1.

As shown in TABLE 4, based on the relationship between the film formation rate and the film formation time determined from the film formation conditions, the thickness of the high-absorption amorphous silicon carbide layer 30a was determined to be approximately 7 nm, and the thickness of the low-absorption amorphous silicon carbide layer 30b was determined to be approximately 3 nm.

On the other hand, during the formation of the buffer layer 30d, after the low-absorption amorphous silicon carbide layer 30b was formed, the plasma was stopped without stopping the supply of the material gas, and the film formation was transitioned from the low-absorption amorphous silicon carbide layer 30b to the buffer layer 30d while continuously adjusting the mixture ratios of the material gas. The other conditions were set basically identical to those of Example 1.

### Comparative Example 1

During the transition from the film formation of the low-absorption amorphous silicon carbide layer 30b to the film formation of the buffer layer 30d, the film formation chamber was once discharged and vacuumed while the plasma was stopped and the gas was no longer supplied. Then, the buffer layer 30d was formed. The other conditions were set basically identical to Example 3.

### Comparative Example 2

The high-absorption amorphous silicon carbide layer 30a and the low-absorption amorphous silicon carbide layer 30b were not formed, and only the interface layer 30c in which the flow rate of diborane was continuously changed was formed. The film formation time was adjusted such that the thickness of the interface layer 30c was approximately 10 nm.

In addition, during the transition from the film formation of the low-absorption amorphous silicon carbide layer 30b to the film formation of the buffer layer 30d, the film formation chamber was once discharged and vacuumed while the plasma was stopped and the gas was no longer supplied. Then, the buffer layer 30d was formed.

TABLE 5 shows the open voltage Voc, the short-circuit current density Jsc, the fill factor FF, and the efficiency of each of the tandem-type solar cells 100 of Examples 1-3 and Comparative Examples 1 and 2. In TABLE 5, ratios of the values of Examples 1-3 and Comparative Example 2 when the open voltage Voc, the short-circuit current density Jsc, the fill factor FF, and the efficiency in Comparative Example 1 were set as 1 are shown.

TABLE 5

| | | SHORT- | | |
|---|---|---|---|---|
| | | CIRCUIT | | |
| | OPEN | CURRENT | | |
| | VOLTAGE | DENSITY | | |
| | Voc | Jsc | FF | EFFICIENCY η |
| EXAMPLE 1 | 1.01 | 1.00 | 1.01 | 1.02 |
| EXAMPLE 2 | 1.01 | 1.00 | 1.01 | 1.02 |
| EXAMPLE 3 | 1.02 | 1.00 | 1.00 | 1.02 |
| COMPARATIVE | 1 | 1 | 1 | 1 |
| EXAMPLE 1 | | | | |
| COMPARATIVE | 1.01 | 1.00 | 0.95 | 0.97 |
| EXAMPLE 2 | | | | |

When the high-absorption amorphous silicon carbide layer 30a and the low-absorption amorphous silicon carbide layer 30b were consecutively formed and the interface layer 30c was provided as in Examples 1 and 2, the open voltage Voc and the fill factor FF were improved compared to Comparative Examples 1 and 2.

This can be deduced to be because formation of the plasma generated initial layer at the interface between the high-absorption amorphous silicon carbide layer 30a and the low-absorption amorphous silicon carbide layer 30b is prevented and the defect at the interface between the high-absorption amorphous silicon carbide layer 30a and the low-absorption amorphous silicon carbide layer 30b is reduced.

Moreover, in the formation of the buffer layer 30d, when the film formation was executed from the low-absorption amorphous silicon carbide layer 30b to the buffer layer 30d in a manner to not stop the supply of gas and stop the plasma after the low-absorption amorphous silicon carbide layer 30b is formed as in Example 3, the open voltage Voc was improved compared to Comparative Example 1, and the open voltage Voc and the fill factor FF were improved compared to Comparative Example 2.

This can be deduced to be because the detachment of hydrogen from the surface of the low-absorption amorphous silicon carbide layer 30b is prevented, it becomes difficult for the impurities (contaminations) attached to the chamber wall of the film formation chamber to hit the gas molecule and reach the surface of the low-absorption amorphous silicon carbide layer 30b, and the defect density at the interface between the low-absorption amorphous silicon carbide layer 30b and the buffer layer 30d is reduced.

What is claimed is:

1. A method of manufacturing a solar cell, comprising:
a first step in which a p-type layer is formed;
a second step in which an i-type amorphous silicon layer is layered and formed over the p-type layer; and
a third step in which an n-type layer doped with an n-type dopant is layered and formed over the i-type amorphous silicon layer, wherein
in the first step, a doping concentration of a p-type dopant included in the p-type layer is increased as a distance from the i-type amorphous silicon layer is increased.

2. The method of manufacturing a solar cell according to claim 1, wherein
the first step comprises:
forming a high-absorption amorphous silicon carbide layer doped with the p-type dopant in a first dopant concentration, and a low-absorption amorphous silicon carbide layer doped with the p-type dopant in a second dopant concentration which is lower than the first dopant concentration, on a side nearer to the i-type amorphous silicon layer than is the high-absorption amorphous silicon carbide layer.

3. The method of manufacturing a solar cell according to claim 2, wherein
in the first step, mixture gas including silicon-containing gas, carbon-containing gas, p-type dopant-containing gas, and hydrogen is made into plasma, and the high-absorption amorphous silicon carbide layer and the low-absorption amorphous silicon carbide layer are formed, and
the high-absorption amorphous silicon carbide layer and the low-absorption amorphous silicon carbide layer are consecutively formed while a state of generation of plasma is maintained, and an interface layer is formed between the high-absorption amorphous silicon carbide layer and the low-absorption amorphous silicon carbide layer.

4. The method of manufacturing a solar cell according to claim 1, wherein
in the first step, an amount of supply of p-type dopant-containing gas is changed.

5. The method of manufacturing solar cell according to claim 1, wherein
a microcrystalline silicon solar cell unit including an i-type microcrystalline silicon layer is formed over the n-type layer.

6. The method of manufacturing solar cell according to claim 1, wherein
an intermediate layer made of a transparent conductive film is formed over the n-type layer, and
a microcrystalline silicon solar cell unit including an i-type microcrystalline silicon layer is formed over the intermediate layer.

7. A method of manufacturing a solar cell, comprising:
a first step in which a p-type layer is formed;
a second step in which an i-type amorphous silicon layer is layered and formed over the p-type layer; and
a third step in which an n-type layer doped with an n-type dopant is layered and formed over the i-type amorphous silicon layer, wherein
in the first step, a high-absorption amorphous silicon carbide layer doped with a p-type dopant in a first dopant concentration, a low-absorption amorphous silicon carbide layer formed on a side nearer to the i-type amorphous silicon layer than is the high-absorption amorphous silicon carbide layer and doped with the p-type dopant in a second dopant concentration which is lower than the first dopant concentration, and a silicon carbide buffer layer formed between the low-absorption amorphous silicon carbide layer and the i-type amorphous silicon layer are formed.

8. The method of manufacturing a solar cell according to claim 7, wherein
the first step comprises:
making mixture gas including silicon-containing gas, carbon-containing gas, p-type dopant-containing gas, and hydrogen into plasma and forming the high-absorption amorphous silicon carbide layer and the low-absorption amorphous silicon carbide layer, and
making mixture gas including silicon-containing gas, carbon-containing gas, and hydrogen into plasma and forming the silicon carbide buffer layer, and
after the low-absorption amorphous silicon carbide layer is formed, the plasma is temporarily stopped, supply gas is adjusted, and the plasma is again generated to stepwise form the silicon carbide buffer layer.

9. The method of manufacturing a solar cell according to claim 8, wherein
the inside of a film formation chamber is not discharged to vacuum before mixture ratios of the supply gas are adjusted.

10. The method of manufacturing a solar cell according to claim 7, wherein
a microcrystalline silicon solar cell unit including an i-type microcrystalline silicon layer is formed over the n-type layer.

11. The method of manufacturing solar cell according to claim 7, wherein
an intermediate layer made of a transparent conductive film is formed over the n-type layer, and
a microcrystalline silicon solar cell unit including an i-type microcrystalline silicon layer is formed over the intermediate layer.
